(19) United States
(12) Patent Application Publication
(10) Pub. No.: US 2026/0237960 A1
(43) Pub. Date: Aug. 13, 2026

(54) LASER ARRAY UNIT

(71) Applicant: HEARTRAY LTD, Kibutz Haogen (IL)

(72) Inventors: Eran HOCHSTADTER, Kibbutz Haogen (IL); Ran CALIFA, Givatayim (IL); Matan BENYAMIN, Givatayim (IL)

(21) Appl. No.: 19/152,616

(22) PCT Filed: Feb. 7, 2024
(86) PCT No.: PCT/IL2024/050145

§ 371 Date: Jul. 31, 2025

Related U.S. Application Data
(60) Provisional application No. 63/444,085, filed on Feb. 8, 2023.
(60) Provisional application No. 63/523,149, filed on Jun. 26, 2023.

(51) Int. Cl. H01S 5/02253; G01B 9/02; H01S 5/42

(52) U.S. Cl. CPC H01S 5/02253; G01B 9/02094; H01S 5/423

(57) ABSTRACT

A light source unit comprising an array of a plurality of single mode Vertical Cavity Surface Emitting lasers (VCSELs) having a selected arrangement, and an array of lenses comprising a plurality of lens units each associated with a respective single mode VCSEL. The plurality of lenses have selected focal length and are positioned at a selected distance from said plurality of VCSELs to provide a plurality of generally collimated output beams, and wherein said plurality of generally collimated output beams are non-parallel between them.

### TECHNOLOGICAL FIELD

The present disclosure relates to an array of Vertical Cavity Surface Emitting lasers (VCSEL) and a device utilizing such array for use in combination with driving monitoring system (DMS)

### BACKGROUND

Driver monitoring system (DMS) is a vehicle safety system used for analyzing and monitoring Driver's condition, and alert or take actions to reduce risk of crash of the vehicle. Typical DMS utilizes one or more camera units and control system operable for collecting and analyzing data on driver's attention, alertness, and possibly other biomedical conditions.

DMS systems are considered as high-level safety system for road vehicles. Such systems enter the list of required safety system to provide reliable monitoring of driver's alertness and awareness. This is of specific importance in vehicles utilizing assistive driving functions.

VCSEL technology has become an increasingly popular choice for implementation in automotive production due to its high power, robustness, and cost-effectiveness. Further VCSELs' structure results in narrow bandwidth as compared to LED, providing improved temporal coherence and signal to noise ratio when needed. In recent years, a driving monitoring system (DMS) has been developed to provide real-time evaluation of the presence and state of the driver. This DMS includes a camera-based system pointed at the driver's face to provide alerts to the driver and initiate an intervention to manage the control of the vehicle when necessary. This technology helps to improve safety on the road and provides better control over the vehicle.

Speckle patterns are patterned of light and dark regions formed within an illuminated region due to coherence of light. Speckles are typically considered as noise, however various techniques are known, utilizing speckle analysis for remote monitoring of selected parameters. Laser Speckle Contrast Analysis (LASCA) is a technique enabling monitoring and analysis of blood perfusion and blood flow in tissue based on variation in contrast of speckle patterns. This technique enables determining data such as heart rate, heart rate variability, and in some cases even blood pressure and breathing rate.

For example, A. F. Fercher et al, “Flow visualization by means of single-exposure speckle photography”, Opt. Commun., 37 (5), 326-330 (1981), describes the use of LASCA where a photograph of a flow field is taken under laser illumination. If the exposure is short enough, the velocity distribution in the field will be mapped on the photograph as variations in speckle contrast. These contrast variations can be converted to intensity variations by means of a simple spatial filtering technique, to give a direct picture of the velocity distribution in the flow field. A potential application of this technique to the mapping of retinal blood flow is described.

P. Vaz, et al “Laser speckle contrast analysis for pulse waveform extraction”, in Novel Biophotonics Techniques and Applications III, A. Amelink and I. Vitkin, eds., Vol. 9540 of SPIE Proceedings (Optica Publishing Group, 2015), paper 954007 shows a method for pulse waveform extraction using laser speckle contrast analysis. An experimental apparatus was assembled, using a coherent light source and a digital video camera to record time varying speckle patterns emitted from the radial artery. The speckle data were analyzed by computing the speckle pattern contrast on a sequence of video frames. The speckle pulse wave signal was then compared with a photoplethysmographic signal both time and frequency domain. A total of thirty datasets were acquired from 10 individuals. Subjects heart rate was identified with a root mean square error of 1.3 beats per minute. Signals similarity was evaluated using spectral coherence with an overall mean coherence of 0.63. Speckle contrast analysis is a newly commercialized technique to monitor microvascular blood flow. However, these results demonstrate the ability of the same technique to extract pulse waveform information. The inclusion of this feature in the current speckle devices is only associated with a slightly change in the signal processing techniques and video acquisition parameters but can be very useful in clinical context.

### GENERAL DESCRIPTION

Driver monitoring systems are increasingly becoming essential safety elements in vehicles. Typical driver monitoring systems often utilize image processing to determine driver conditions and alert levels to enhance road safety.

Monitoring biomedical and physiological parameters of the driver can provide valuable data on driver's condition. Speckle analysis, and specifically Laser Speckle Contrast Analysis (LASCA) technique enable remote and contactless collection of biomedical and physiological parameters such as heart rate, heart rate variability (HRV), breathing rate, blood perfusion level and more.

Determining such parameters using spackle analysis generally require coherent illumination, giving rise to spackle patterns due to self-interference between light components. The present disclosure provides a light source unit configured to provide an illumination pattern comprising coherent illumination, while being adapted for use in typical vehicle space and integration with existing and typical driver monitoring systems (DMS).

To this end the present disclosure provides a light source unit comprising an array of a plurality of single mode Vertical Cavity Surface Emitting lasers (VCSELs). The plurality of VCSEL unit is configured with a selected arrangement and are associated with a selected optical element providing a pattern of generally collimated and non-parallel output beams. Divergence angle of the generally collimated beams, and angular relations between the beams are selected to provide an illumination pattern in the form of a plurality of illumination spots at a selected range from the system. In this connection the term ‘generally collimated’ as used herein may refer to output illumination beam having divergence angle within a selected range between 0.1 and 3 degrees, and preferably between 0.5 and 2 degrees.

Generally, such light source may be placed within a vehicle, where a head box of a driver may be located at a selected distance from a location of the light source. Additionally, the arrangement of the output beams is configured to generate a selected pattern of illumination spots enabling collection of image data, where a number of sufficiently separated illumination spots fall within headbox of the driver.

Further, the light source of the present disclosure may also be used in various other environments and may for example be embedded in electronic devices such as laptops, smartphones, display screens or other devices, to provide selected monitoring functions.

The light source unit may comprise one or more additional arrangements of VCSEL units, typically comprising multimode VCSEL units, emitting illumination of increased intensity and reduced coherence, that are useable for flood illumination and/or illumination pattern allowing depth detection.

The light source unit may be formed on a common substrate forming a single VCSEL chip carrying one or more arrays of VCSEL units. This enables a relatively low-cost manufacturing and integration with conventional DMS systems.

Thus, according to a broad aspect, the present disclosure provides a light source unit comprising an array of a plurality of single mode Vertical Cavity Surface Emitting lasers (VCSELs) having a selected arrangement, and an array of lenses comprising a plurality of lens units each associated with a respective single mode VCSEL, wherein said plurality of lenses have selected focal length and are positioned at a selected distance from said plurality of VCSELs to provides a plurality of generally collimated output beams, and wherein said plurality of generally collimated output beams are non-parallel between them.

Output beams of the plurality of single mode VCSELs may have divergence angle between 0.1 and 4 degrees, or between 0.1 and 2 degrees, or between 0.5 and 2 degrees. According to some embodiments, the light source unit may comprise an additional lens located downstream of said plurality of lens unit and having an effective area covering a first plurality of VCSELs out of said plurality of VCSELs, said additional lens thereby provides variation in angular direction between said plurality of generally collimated output beams to be non-parallel.

According to some embodiments, the plurality of lens units comprises lens units having shifted position with respect to emission aperture of the respective VCSEL units, thereby shifting angular direction of the respective generally collimated output beams.

According to some embodiments, the lens units may have shifted position, are each shifted by a different amount in at least one of direction and length providing non-parallel generally collimated output beams.

According to some embodiments, the light source unit may further comprise a second array of multimode VCSELs positioned at a side of said array of single mode VCSELs.

According to some embodiments, the array of single mode VCSELs and said second array of multimode VCSELs are formed on a common substrate.

According to some embodiments, the second array is configured to provide flood illumination within a selected range.

According to some embodiments, the second array is configured to provide patterned illumination formed of a plurality of spatially separated illumination spots having a predetermined arrangement.

According to some embodiments, the plurality of non-parallel generally collimated output beams is configured to form a predetermined pattern of non-overlapping illumination spots at a selected range from the light source unit.

According to some embodiments, the predetermined pattern comprises illumination spots spatially interfacing between them.

According to some embodiments, the plurality of non-parallel generally collimated output beams is configured to form a predetermined pattern of partially overlapping illumination spots at a selected range from the light source unit.

According to some embodiments, the selected range from the light source unit may be determined based on a typical distance between dashboard and driver's head within a vehicle.

According to some embodiments, the selected range from the light source unit is between 40 cm and 120 cm.

According to some embodiments, the plurality of non-parallel generally collimated output beams is configured to form a predetermined pattern of non-overlapping illumination spots covering an area of dimensions between 40 cm×40 cm to 100 cm×100 cm.

According to some embodiments, the plurality of non-parallel generally collimated output beams is configured to form a predetermined pattern comprising a selected number of sub-patterns configured to illuminate a selected number of regions within an illuminated space.

According to some embodiments, the VCSELs are configured to emit a generally monochromatic electromagnetic radiation within a wavelength range between 800 nm and 1100 nm.

According to some embodiments, the array of a plurality of single mode VCSELs is operable to emit a selected temporal pattern of illumination pulses of selected duration.

According to another broad aspect, the present disclosure provides a light source unit comprising an array of a plurality of single mode Vertical Cavity Surface Emitting lasers (VCSELs) having a selected arrangement, and an optical unit configured to apply selected optical power to output illumination from said plurality of VCSELs to provide a plurality of generally collimated output beams, and wherein said plurality of generally collimated output beams are non-parallel between them. The optical element may comprise a lenslet array, diffractive grating array, manufactured optical element determined by free-form optical planning etc.

According to one other broad aspect, the present disclosure provides a driver monitoring system comprising at least one light source unit and at least one camera; said at least one light source unit comprises the light source unit as described herein.

According to some embodiments, the driver monitoring system may be configured for utilizing coherent illumination emitted by said array of single mode VCSELs for determining one or more driver's biomedical parameters by analysis of speckle patterns generated by the coherent illumination.

According to some embodiments, the analysis of speckle patterns comprises analysis of contrast variation in speckle patterns.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 illustrates schematically a light source unit formed of a plurality of single mode VCSELs according to some embodiments of the present disclosure;

FIG. 2 exemplifies a general layered configuration of a VCSEL;

FIGS. 3A and 3B illustrate optical arrangement including a lens array used with VCSEL array according to some embodiments of the present disclosure, FIG. 3A exemplifies the VCSEL and lens array, and FIG. 3B exemplifies geometrical arrangement and positioning of the lens array;

FIG. 4 exemplifies an additional lens configuration according to some embodiments of the present disclosure;

FIG. 5 exemplifies light source unit and generated illumination pattern according to some embodiments of the present disclosure;

FIGS. 6A to 6D exemplify spatial relation between illumination spots according to some embodiments of the present disclosure, FIG. 6A shows well separated illumination spots; FIG. 6B shows interfacing illumination spots, FIG. 6C illustrates illumination spots with low overlap, and FIG. 6D illustrates illumination spots with increased overlap;

FIG. 7 exemplifies a light source unit including an additional multimode VCSEL array according to some embodiments of the present disclosure; and

FIG. 8 exemplifies a single mode VCSEL array according to some embodiments of the present disclosure formed with two or more separately operated regions.

### DETAILED DESCRIPTION OF EMBODIMENTS

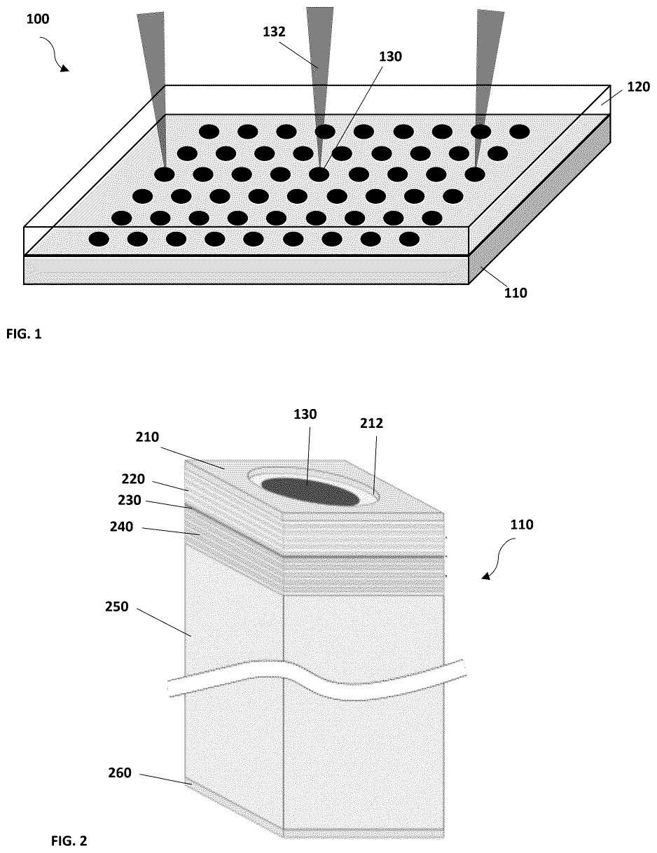

As indicated above, the present disclosure provides a light source unit including a plurality of single mode Vertical Cavity Surface Emitting lasers (VCSELs). Reference is made to FIG. 1 schematically illustrating light source unit 100 according to some embodiments of the present disclosure. The light source unit 100 includes a substrate 110, typically made as a multilayer substrate having a layered arrangement forming a vertical cavity. The substrate carries a plurality of single mode VCSELs 130, operable for emitting optical radiation in a selected wavelength range. The light source unit 100 also includes an optical element 120, such as a lens array, diffractive optical element, etc., configured for manipulating output beams 132 of the single mode VCSELs to provide an arrangement of generally collimated beams propagating in a non-parallel relation toward a selected region, to thereby generate a selected illumination pattern of the selected region.

In this connection, FIG. 2 illustrates a general diagram of a VCSEL unit 130. the VCSEL unit 130 is based on a layered substrate 110 including a top electric contact 210, having an aperture 212. the electric contact may be placed on a top Bragg reflector 220 and a bottom Bragg reflector 240, where a quantum well layer 230 is located between the top 220 and bottom 240 Bragg reflectors. The bottom Bragg reflector 240 is located on a substrate 250, typically being a semiconductor substrate, and a bottom electric contact 260.

The layered structure of substrate 110 provides a vertical cavity, enabling optical emission through aperture 212 in response to sufficient electric power provided between top 210 and bottom 260 electric contacts. Typically, VCSEL units has relatively short optical cavity leading to high free spectral range (FSR) and high distance between longitudinal modes. VCSEL properties often provide narrow wavelength range and low longitudinal mode count. Accordingly, VCSEL lasing modes typically relate to spatial (transverse) modes, determined by VCSEL diameter. Accordingly, diameter of the aperture 212 defines transverse spatial modes supported by the VCSEL unit 130. A larger aperture generally supports several spatial transverse modes and allows higher power output, while smaller aperture may support a single mode and provide limited power output. Such single mode VCSEL can provide illumination with increased coherence with respect to multimode VCSEL as it supports a single spatial mode in a generally gaussian form. The light source unit 100 utilizes an array of single mode VCSELs to overcome power limitations associated with low diameter of a single mode VCSEL, and to provide a selected illumination pattern formed of a plurality of illumination spots.

It should also be noted that the high FSR typical to VCSELs effectively provides a laser source that is generally insensitive to temperature fluctuations with respect to edge emitter laser types. This provides reduce wavelength drift increase the contrast of speckle patterns generated by single mode VCSEL illumination and obviates the need for thermal stabilization.

Further, VCSEL laser units can generally be manufactures in bulk at relatively low cost and provide a reliable production line. A single chip can carry a plurality of VCSEL emitters having selected properties, which may be similar or different between them as described in more detail further below. Additionally, the light source unit 100 of the present disclosure may be configured for use with a driver monitoring system (DMS). such DMS is typically configured for monitoring one or more parameters of a driver, to detect variations in driver awareness level and raise an alert if the driver seems not focused. the light source unit 100 of the present disclosure provides coherent illumination pattern that is typically directed at the driver but may be directed at one or more other individuals in the vehicle. Coherent illumination from the light source unit of the present disclosure may be used for determining one or more biomedical and/or physiological parameters of the driver (or other persons) using speckle analysis.

Laser Speckle Contrast Analysis (LASCA) is a generally known technique utilizing variation in contrast of speckle patterns to determine one or more parameters of a person. the speckle patterns are formed due to certain self-interference between coherent light components of an optical beam illuminating a region of a body. Variation in the body surface may case shifting in the spackle pattern, which may typically be collected as reduced contrast due to smearing of the pattern within exposure time of image collection. Monitoring such variations through time can be used to determine parameters such as heart rate, heart rate variability, perfusion levels, breathing rate etc.

The DMS may also utilize a light source for generating selected illumination to enhance image processing capabilities. Such selected illumination pattern may include flood illumination and/or a patterned illumination formed by spatially separated illumination spots. As discussed further below, the use of VCSEL unit as light source enables simple and direct integration with such DMS, where a single chip can carry a plurality of VCSEL emitters that may be similar or different in emission properties.

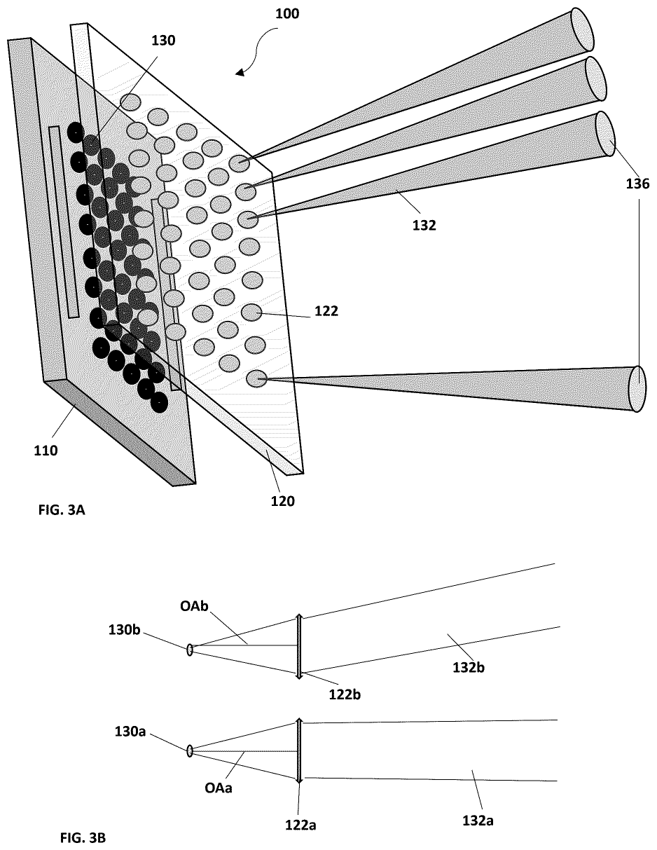

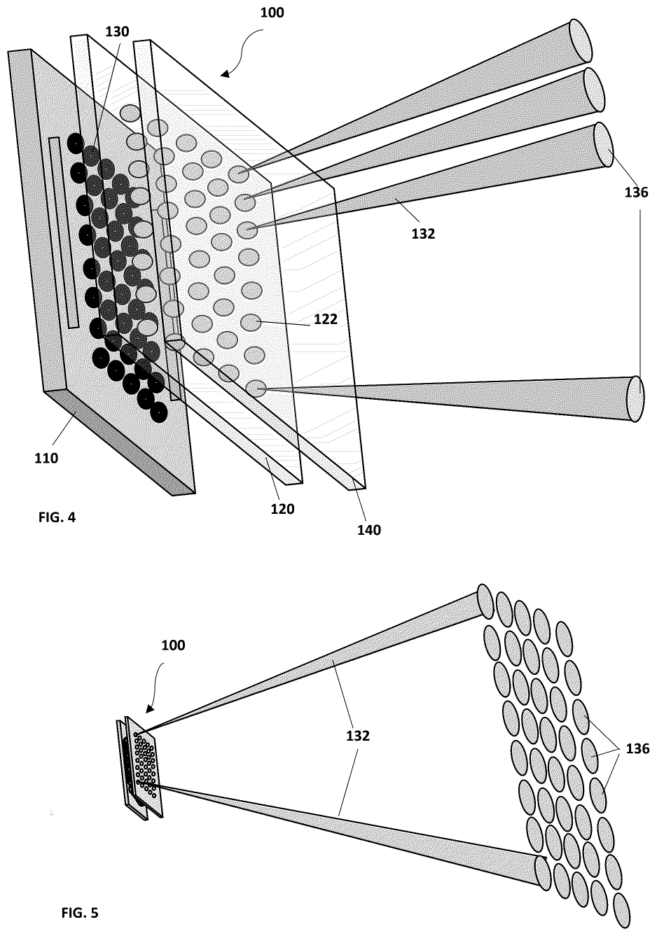

Generally, the light source unit may be formed on a chip having selected dimensions, between a few millimeters to one or two centimeters. Further, to provide efficient illumination pattern at driver head box region, the illumination pattern may be expanded in both selected divergence angle of each of the output beams and relative propagation paths of the output beams. In this connection reference is made to FIGS. 3A-3B and FIG. 4 illustrating selected configurations of the light source unit 100 according to some embodiments of the present disclosure.

FIG. 3A illustrates a light source unit 100 including an array of single mode VCSELs 130, and a respective array of lenses 120. The array of lenses 120 may be configured in various techniques such as a microlens array, lenslet array, array of diffractive lenses, etc., and effectively includes a plurality of lens regions 122, each associated with a respective one of the single mode VCSELs 130. Typically, single mode VCSELs have relatively small output aperture, resulting in relatively large divergence angle. The array of lenses 120 includes lenses regions 122 having selected optical power and is located at a selected distance to adjust the output beam and provide generally collimated output beams 132. In this connection, the term generally collimated is to be understood broadly and relates to beams having a selectively low divergence angle. More specifically, the generally collimated output beams 132 have divergence angle selected to generate an illumination spot 136 of selected spot area at a selected distance. For example, for a headbox distance between 40 cm and 120 cm from the light source unit (typical in driving conditions), divergence angle of between 0.1 and 4 degrees of the output beams can be selected, to provide illumination spots having area of a few millimeters squared to a few centimeters squared. In some configurations the divergence angle of the output beams may be selected between 0.5 and 2 degrees.

Additionally, the pattern generated by the plurality of illumination spots are preferably arranged in space to cover a headbox region of a driver. For example, a total coverage is of the illumination pattern may have area of 40×40 cm² to 100×100 cm². To this end the plurality of output beams is directed in non-parallel paths, where each output beam propagates at a slightly different angle from other beams to generate the resulting illumination pattern as illustrated in FIG. 3A. To this end the array of lenses 120 is configured to apply selected spatial phase shift or spatial chirp to direct the output beams in a selected non-parallel pattern. For example, the array of lenses 120 may include lens units 122 that are shifted in position with respect to emission aperture of the respective VCSEL units 130. Such position shift introduces angular variation in propagation path of the output beam. alternatively, the different lenses 122 may have selected phase variations, provided to vary angular direction of propagation of the output beam. In some configurations the array of lenses may have a tailored design determining by free form optical design to provide coherent output beams having selected divergence angle and propagating in a selected non-parallel angular relation.

FIG. 3B exemplifies spatial shift in optical axis of the lens with respect to optical axis of the respective VCSEL unit, and the resulting variation in propagation path. As shown in FIG. 3B, lens 122a is positions such that optical axis OAa thereof coincides with optical axis of VCSEL 130a. As a result, output beam 132a is generally parallel to the optical axis OAa. Alternatively, lens 122b is placed at a location shifted upward with respect to optical axis of the respective VCSEL 130b. The spatial shift in lens location results in spatial phase shift of the output beam and this in an output beam directed at an angle with respect to the optical axis, where the angle of propagation depends on direction of the spatial shift and shift size.

To provide a selected pattern, output beam 132 of each of the VCSELs 130 are non-parallel to each other. To this end in some embodiments, each of the lenses 122 or the array 120 may apply a selected phase shift (e.g., by spatial shift), determined in accordance with location of the lens 122 within the array 120. For example, a central point of the VCSEL array may be determined, and each lens 122 may be shifted by a factor of its distance from the central point, in a direction extending away (or towards) the central point. This spatial shift pattern can provide a phalanx-like arrangement of the different output beams to cover a selected region.

An alternative configuration is illustrated in FIG. 4. In this configuration, the light source unit includes an array of single mode VCSELs 130, each VCSEL is associated with a lens 122 of the lens array 120, providing selected collimation level of the output beams as described above. Additionally, the light source unit in this embodiment includes an additional optical element 140 located downstream of the lens array 120. Optical element 140 may be a lens unit, diffractive element etc., and is configured to cover the plurality of lens units 122 covering surface area of the array of single mode VCSELs. Optical element 140 is defined by a selected optical axis and varies angular direction of output beams in accordance with location of the beam source with respect to optical axis thereof. More specifically, optical element 140 may be represented by a lens unit having optical axis aligned with a central point of the array 130. Output beams 132, emitted at locations other than the central point are shifted from the optical axis, resulting in angular shift of beam propagation direction.

Reference is now made to FIG. 5 illustrating general configuration of the light source unit and illumination pattern thereof. As shown, light source unit 100 is configured to be positioned at a selected location and configured to generate an illumination pattern formed of a plurality of coherent illumination spots 136 at a selected distance (e.g., 40-120 cm). The arrangement of illumination spot may be any arrangement providing limited or no overlap between adjacent spots 136, such that the illumination spots 136 include certain region of coherent illumination, enabling speckle analysis based on light collection of the illumination spots. Spatial arrangement of the illumination pattern may be any arrangement including rectangular array as illustrated in FIG. 5, hexagonal array, triangular array, or any other selected spatial arrangement. The spatial arrangement of the array may also include one or more, or two or more separate regions having separated and/or different illumination pattern arrangement. For example. the light source unit 100 may be configured to direct a portion of the output beams to form an illumination pattern where driver head box may be located, and an additional, auxiliary, arrangement of output beams directed at a region where passenger head box may be located. This enables the use of a single light source unit for monitoring one or more individuals within a common vehicle.

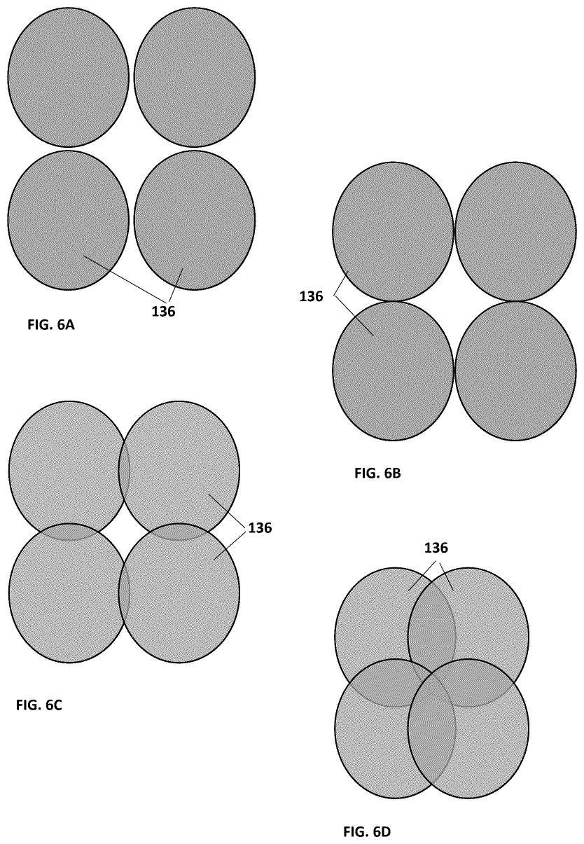

FIGS. 6A to 6D illustrate various spatial relationships between illumination spots. FIG. 6A illustrates spatially separated illumination spots 136, FIG. 6B shows interfacing illumination spots, FIG. 6C shows illumination spots having low partial overlap (e.g., below 10% surface area overlap), and FIG. 6D shows illumination spots with increased partial overlap (e.g., above 10% surface area overlapping). Arrangement of the illumination spots 136 within a selected pattern may be used for providing selected functionalities and/or additional functionalities supported by the light source unit 100.

To obtain image data suitable for spackle analysis, a sufficient portion of the illumination spots 136 is preferably non-overlapping. This provides a portion of the illumination spot being under coherent illumination, giving rise to speckle pattern within illumination spot 136.

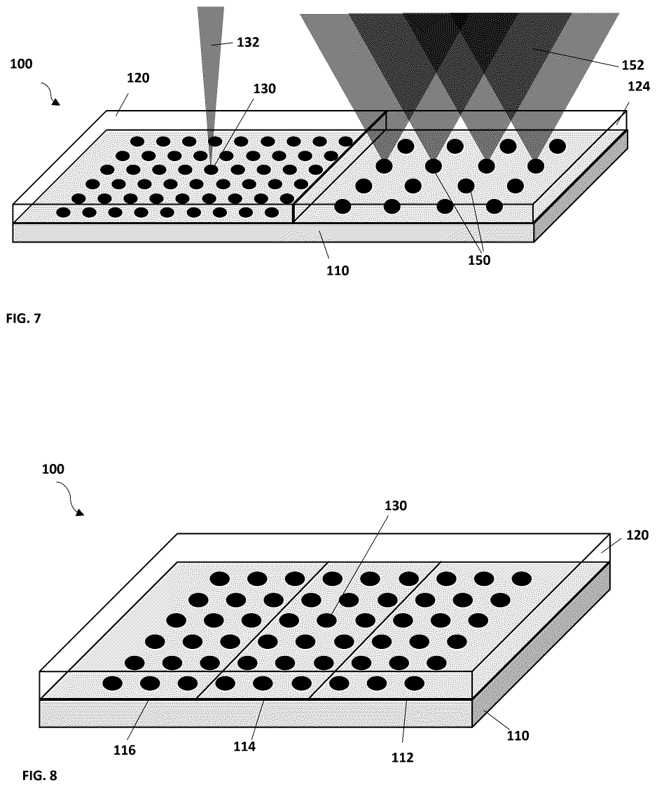

Further, typical DMS may often be used to provide additional monitoring techniques. To this end the light source unit 100 may be configured to provide illumination pattern supporting further image processing functionalities. For example, spatially separated light spots on the illumination pattern can be used for depth perception and three-dimensional mapping using variation in spot size in the resulting images. Additionally, partial overlap between the light spots may provide field illumination suitable for various image processing techniques, providing relatively uniform illumination of the driver headbox region. Accordingly, typically illumination pattern generated by the array of single mode VCSELs as illustrated in FIGS. 6A to 6C may be suitable for speckle analysis according to embodiments of the present disclosure. This is while illumination pattern as illustrated in FIG. 6D, i.e., having large overlap between light spots, may be less preferrable for spackle analysis. Generally, contrast of speckle patterns is reducing when the pattern is formed by illumination of two or more (or a number n) light sources by 1/sqrt(n), thus overlap between illumination spots generated by different VCSELs 130 of the array reduces speckle contrast within the overlapping region. However, the light source unit 100 of the present disclosure may still provide such illumination pattern as exemplified in FIG. 7 below, typically for flood illumination purposes.

FIG. 7 illustrates a combined light source unit 100 according to further some embodiments of the present disclosure. This this example, a common chip 110 carries an array of single mode VCSELs 130 and an additional array of multimode VCSELs 150. The single mode VCSELs are associated with optical element 120 as described above to provide an array of non-parallel, generally collimated output beams 132. The array of multimode VCSELs may also be associated with an optical element 124 such as a diffuser an energized diffuser, or a homogenizer, and is configured to generate output light in the form of a plurality of output beams 152. Illumination pattern of the multimode VCSELs array 150 may be selected to provide spatially separated light spots as illustrated in FIG. 6A to support three-dimensional analysis of the illuminated region. Alternatively, as illustrated in FIG. 7, the illumination pattern may include overlapping output beams generating field illumination suitable for general image processing operated by a typical DMS system.

The light source unit 100 may be operable in a selected illuminations sequence to allow multiplexing between two or more DMS functionalities. For example, an illumination sequence may include coherent illumination using the single mode VCSEL array for a first duration, followed by incoherent, field illumination using the array of multimode VCSELs for a second duration, and/or a spatially separated patterned illumination for three-dimensional recognition of the space. Image collection by the DMS may be aligned with illumination sequence to utilize coherent illumination for speckle analysis and determining biomedical parameters of the driver or other people in the vehicle. And for using incoherent field illumination for image processing such as gaze detection, head orientation, eye movement etc.

Additionally, FIG. 8 illustrates another example of the light source unit 100. Although only the single mode VCSEL array 130 is illustrated, the light source in this embodiment may be formed according to the embodiment on FIG. 7 including an additional VCSEL array. Further, the array of single mode VCSELs 130 may be separated into two or more, e.g., three or more as illustrated in FIG. 8, regions, or sub-arrays of single mode VCSELS, e.g., sub array 112, 114 and 116. The different sub-arrays 112-114 and 116 may be separately operable and configured to direct illumination patterns formed by pluralities of generally collimated non-overlapping output beams toward different sections of the illuminated region. The different sub-arrays may be selectively operated to allow energy saving and reduce heat dissipation in the VCSEL chip. For example, a DMS system may be mounted and aligned for covering headbox of various drivers. During operation, the DMS may identify that the driver's head is actually at a top portion of the illumination region (or at a bottom portion thereof, or at central portion thereof). In response, the DMS may proceed by operating only sub-array of the single mode VCSELS directing output beams at the relevant portion of the illumination region and reducing energy demand and heat generated by the system.

Thus, the present disclosure provides a light source unit comprising an array of single mode VCSELs and respective optical element to provide output illumination in the form of generally collimated non-parallel output beams. The light source unit may be an integrated light source unit formed on a single, common chip, and may include one or more additional VCSEL arrays, typically being multimode arrays. The light source unit may provide total output power in the range of 2 W to 10 W and may include an arrangement of 100 to 10000 single mode VCSELs, or 1000-6000 single mode VCSELs, or 1500-4000 single move VCSELs, to provide desired illumination pattern as described herein. The light source unit, and/or its respective array of single mode VCSELs may be operable for pulsed illumination including pulses of duration between 30 millisecond to 30 microsecond, allowing time multiplexing of illumination conditions and image collection for selected processing applications. The light source unit may be operable to emit generally monochromatic illumination in one or more wavelengths range of 800 nm to 1100 nm. For example, the output wavelength may include 850 nm and/or 940 nm. In this connection, the term generally monochromatic relates to continuous wave (CW) illumination having narrow illumination bandwidth of e.g., up to 50 nm or up to 20 nm or up to 10 nm or up to 5 nm.

It is to be noted that the various features described in the various embodiments can be combined according to all possible technical combinations.

It is to be understood that the invention is not limited in its application to the details set forth in the description contained herein or illustrated in the drawings. The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based can readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

1. A light source unit comprising an array of a plurality of single mode Vertical Cavity Surface Emitting lasers (VCSELs) having a selected arrangement, and an array of lenses comprising a plurality of lens units each associated with a respective single mode VCSEL, wherein said plurality of lenses have selected focal length and are positioned at a selected distance from said plurality of VCSELs to provide a plurality of generally collimated output beams, and wherein said plurality of generally collimated output beams are non-parallel between them.

2. The light source unit of claim 1, comprising an additional lens located downstream of said plurality of lens unit and having an effective area covering a first plurality of VCSELs out of said plurality of VCSELs, said additional lens thereby provides variation in angular direction between said plurality of generally collimated output beams to be non-parallel.

3. The light source unit of claim 1, wherein said plurality of lens units comprise lens units having shifted position with respect to emission aperture of the respective VCSEL units, thereby shifting angular direction of the respective generally collimated output beams.

4. The light source unit of claim 3, wherein said lens units having shifted position, are each shifted by a different amount in at least one of direction and length providing non-parallel generally collimated output beams.

5. The light source unit of claim 1, further comprising a second array of multimode VCSELs positioned at a side of said array of single mode VCSELs.

6. The light source unit of claim 5, wherein said array of single mode VCSELs and said second array of multimode VCSELs are formed on a common substrate.

7. The light source unit of claim 5, wherein said second array is configured to provide flood illumination within a selected range.

8. The light source unit of claim 5, wherein said second array is configured to provide patterned illumination formed of a plurality of spatially separated illumination spots having a predetermined arrangement.

9. The light source unit of claim 1, wherein said plurality of non-parallel generally collimated output beams are configured to form a predetermined pattern of non-overlapping illumination spots at a selected range from the light source unit.

10. The light source unit of claim 9, wherein said predetermined pattern comprises illumination spots spatially interfacing between them.

11. The light source unit of claim 1, wherein said plurality of non-parallel generally collimated output beams are configured to form a predetermined pattern of partially overlapping illumination spots at a selected range from the light source unit.

12. The light source unit of claim 9, wherein said selected range from the light source unit being determined based on a typical distance between dashboard and driver's head within a vehicle.

13. The light source unit of claim 9, wherein said selected range from the light source unit is between 40 cm and 120 cm.

14. The light source unit of claim 9, wherein said plurality of non-parallel generally collimated output beams are configured to form a predetermined pattern of non-overlapping illumination spots covering an area of dimensions between 40 cm×40 cm to 100 cm×100 cm.

15. The light source unit of claim 9, wherein said plurality of non-parallel generally collimated output beams are configured to form a predetermined pattern comprising a selected number of sub-patterns configured to illuminate a selected number of regions within an illuminated space.

16. The light source unit of claim 1, wherein said VCSELs are configured to emit a generally monochromatic electromagnetic radiation within a wavelength range between 800 nm and 1100 nm.

17. The light source unit claim 1, wherein said array of a plurality of single mode VCSELs is operable to emit a selected temporal pattern of illumination pulses of selected duration.

18. A driver monitoring system comprising at least one light source unit and at least one camera; said at least one light source unit comprises a light source unit comprising an array of a plurality of single mode Vertical Cavity Surface Emitting lasers (VCSELs) having a selected arrangement, and an array of lenses comprising a plurality of lens units each associated with a respective single mode VCSEL, wherein said plurality of lenses have selected focal length and are positioned at a selected distance from said plurality of VCSELs to provide a plurality of generally collimated output beams, and wherein said plurality of generally collimated output beams are non-parallel between them.

19. The driver monitoring system of claim 18, configured for utilizing coherent illumination emitted by said array of single mode VCSELs for determining one or more driver's biomedical parameters by analysis of speckle patterns generated by the coherent illumination.

20. The driver monitoring system of claim 19, wherein said analysis of speckle patterns comprises analysis of contrast variation in speckle patterns.
